(19) United States
(12) Patent Application Publication
(10) Pub. No.: US 2008/0018375 A1
(43) Pub. Date: Jan. 24, 2008

(54) Level shifter

(75) Inventors: Han-Hsun Chen, Taipei City (TW); Shr-Da Mai, Taipei City (TW); Hsiang-Jui Hung, Taipei City (TW); Ching-Fu Cheng, Taipei City (TW); Sun-Chen Yang, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTek COMPUTER INC.

(21) Appl. No.: 11/802,696

(22) Filed: May 24, 2007

(30) Foreign Application Priority Data
Jul. 21, 2006 (TW) 095126793

(51) Int. Cl. H03L 5/00

(52) U.S. Cl. 327/333

(57) ABSTRACT

A level shifter includes a reference voltage level and a voltage dividing circuit. The voltage dividing circuit is connected to the reference voltage level, a first voltage level, and a second voltage level. The second voltage level is between the reference voltage level and the first voltage level.

### BACKGROUND OF THE INVENTION

1. Field of the Invention

The invention relates to a level shifter, and more particularly, to a level shifter having a voltage dividing circuit

2. Description of the Prior Art

Generally, a level shifter is disposed between two digital circuits for changing a voltage level of an input signal to generate an output signal having another voltage level. For example, a first digital circuit outputs a logic value “0” by generating an output voltage level below 0.2V and outputs another logic value “1” by generating an output voltage level equal to 1V; while a second digital circuit determines an input voltage level to be representative of a logic value “0” if the input voltage level is below 1.5V and determines an input voltage level to be representative of a logic value “1” if the input voltage level is over 4V. Therefore, when the first digital circuit transmits signals to the second digital circuit, the level shifter is required to transform the signal of the voltage level 1V to be a signal having a voltage level of over 4V, so a shifted signal of 5V passed to the following second digital circuit can be correctly determined as having logic “1”. As known to those skilled in this art, the level shifter is widely applied in various circuits, for example, signal exchanging between circuits inside and outside a chip, or signal conversion between internal circuits and external circuits of an LCD panel.

Please refer to FIG. 1. FIG. 1 is a circuit diagram of a conventional level shifter 100. As shown in FIG. 1, the level shifter 100 includes transistors Q1, Q2, resistors R1′, R2′, and voltage sources V1′, V2′. Since connections of these components are shown in FIG. 1, additional details are omitted for the sake of brevity. The function and related operation of the level shifter 100 will be described in detail in the following disclosure.

Assuming the input signal Vᵢₙ has a high voltage level corresponding to a voltage level Va′ and a low voltage level corresponding to a ground voltage 0V, then, when the input signal Vᵢₙ corresponds to the high voltage level, the gate of the transistor Q2 will correspond to the high voltage level simultaneously, the transistor Q2 will be turned on and the voltage level of the node A will be pulled down to the ground voltage. At this point, the gate of the transistor Q2 will correspond to the ground voltage such that the transistor Q2 is turned off. That is, the voltage level of the node B is decided by the voltage source V1′ approximately. Thus, for the subsequent circuit stage, the high voltage level of the output signal Vₒᵤₜ will approximately correspond to the voltage source V1′ by selecting a proper voltage source V1′ and a proper resistor R1′.

When the input signal Vᵢₙ corresponds to the low voltage level 0V, the gate of the transistor Q2 will also correspond to the low voltage level such that the transistor Q2 is turned off. Therefore, the voltage level of the node A is decided by the voltage source V2′. Since the voltage source V2′ is a voltage source with a high voltage level, the gate of the transistor Q1 will correspond to the high voltage level such that the transistor Q1 is turned on. At this point, the voltage level of the node B will be pulled down to the ground voltage 0V due to the conducting transistor Q1. For the subsequent stage, the low voltage level of the output signal Vₒᵤₜ will approximately correspond to the ground voltage 0V.

Nevertheless, the implementation of the level shifter 100 shown in FIG. 1 needs at least two transistors Q1, Q2 and two resistors R1′, R2′. Considering cost, space, and environmental protection factors, a level shifter with fewer components implemented therein is required.

### SUMMARY OF THE INVENTION

It is therefore one of the objectives of the present invention to provide a level shifter with a simple circuit configuration to reduce the cost.

Another objective of the present invention is to provide a level shifter implemented by using components of lower cost.

According to an embodiment of the present invention, a level shifter is provided. The level shifter comprises a reference power level, and a voltage dividing circuit, connected to the reference power level, a first power level, and a second power level, wherein the second power level is between the reference power level and the first power level.

The level shifter of the present invention uses two resistors to form the voltage dividing circuit, thereby achieving the level shifting objective. Therefore, the present invention not only uses fewer circuit components to realize the level shifter function, but also reduces the original high cost caused by implementing too many circuit components in the prior art level shifter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a conventional level shifter.

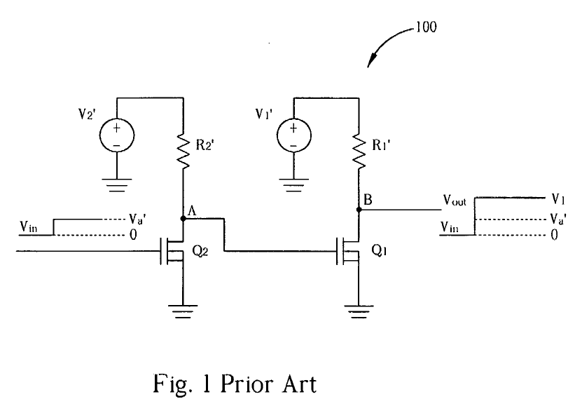

FIG. 2 is a block diagram of a level shifter according to an embodiment of the present invention.

FIG. 3 is a detailed circuit diagram of the level shifter shown in FIG. 2.

FIG. 4 is a detailed circuit diagram of another embodiment of the level shifter shown in FIG. 2.

### DETAILED DESCRIPTION

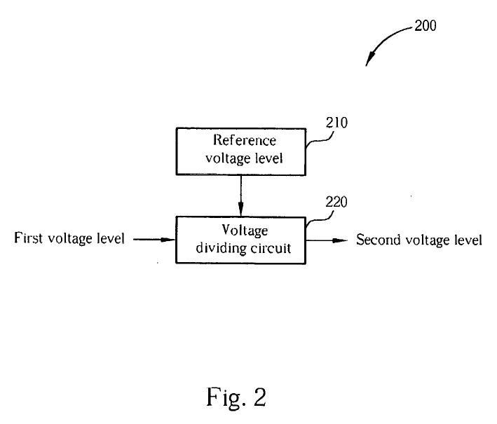

Please refer to FIG. 2. FIG. 2 is a block diagram of a level shifter 200 according to an embodiment of the present invention. As shown in FIG. 2, the level shifter 200 includes a reference voltage level 210 and a voltage dividing circuit 220. The voltage dividing circuit 220 is coupled to the reference voltage level 210, a first voltage level, and a second voltage level. The voltage dividing circuit 220 of the present invention will perform a voltage dividing operation upon the reference voltage level 210 and the first voltage level to generate the second voltage level. In other words, since the voltage dividing circuit 220 performs the voltage dividing operation by using the reference voltage level 210 and the first voltage level, the second voltage level is between the reference voltage level 210 and the first voltage level. In view of the overall circuit configuration of the level shifter 200, the voltage dividing circuit of the level shifter 200 receives a first voltage level and then outputs a shifted second voltage level, thereby achieving the objective of shifting the first voltage level to the second voltage level.

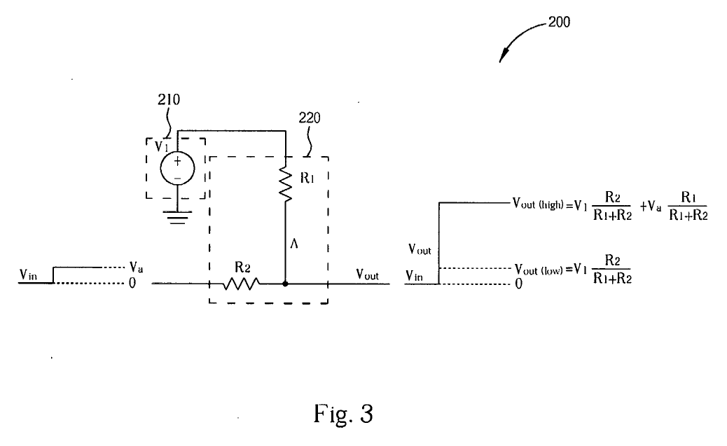

Please refer to FIG. 3. FIG. 3 is a detailed circuit diagram of the level shifter 200 shown in FIG. 2. As shown in FIG. 3, the voltage dividing circuit 220 includes an output node A and two resistors R1, R2. Please note that the resistor R1 is coupled between the reference voltage source (the reference voltage level) 210 and the output node A, and the resistor R2 is coupled between the output node A and an input signal source Vᵢₙ. The function and related operation of the level shifter 200 will be described in detail in the following disclosure.

Assume that the input signal Vᵢₙ generated by the input signal source includes a high voltage level and a low voltage level. The high voltage level is represented by Va. For simplicity, the low voltage level is represented by the ground voltage 0V. Additionally, the reference voltage source will output a reference voltage level V1 continuously, and a voltage Vₒᵤₜ at the output node A therefore can be calculated utilizing superposition as illustrated by the following formula (1):

Vₒᵤₜ=Vᵢₙ*R1/(R1+R2)+V1*R2/(R1+R2) formula (1)

When the input signal Vᵢₙ corresponds to the low voltage level (i.e. the ground voltage 0V), the voltage Vₒᵤₜ at the output node A is represented by the following formula (2):

V_{out(low)}=V1*R2/(R1+R2) formula (2)

When the input signal Vᵢₙ corresponds to the high voltage level (i.e. the voltage level Va), the voltage Vₒᵤₜ at the output node A is represented by the following formula (3):

V_{out(high)}=Va*R1/(R1+R2)+V1*R2/(R1+R2) formula (3)

At this point, after processing by the level shifter 200, the input signal Vᵢₙ originally corresponding to the ground voltage 0V and voltage level Va is converted to an output signal Vₒᵤₜ having a low voltage level V1*R2/(R1+R2) and a high voltage level Va*R1/(R1+R2)+V1*R2/(R1+R2). As mentioned above, a circuit designer can obtain a corresponding proper voltage level of the output signal Vₒᵤₜ by choosing a proper reference voltage level V1. For example, the conventional voltage shifter is used to amplify the level of the input signal Vᵢₙ, while the level shifter 200 of the present invention shifts the original voltage level Va to Va*R1/(R1+R2)+V1*R2/(R1+R2). Therefore, the present invention only needs to set the reference voltage level V1 higher than the original voltage Vᵢₙ and properly tune the resistance of the resistors R1, R2, and then the present invention can amplify the corresponding high voltage level of the input signal Vᵢₙ.

In additional, the corresponding low voltage level of the input signal Vᵢₙ is also converted from the original ground voltage 0V to V1*R2/(R1+R2). As mentioned above, the selected reference voltage level VI is usually not 0V, and the low voltage level V1*R2/(R1+R2) output by the level shifter therefore will be a little higher than the ground voltage 0V. Due to this property, the high voltage level and the low voltage level generated by the level shifter 200 of the present invention can be applied to many fields. For example, the high voltage level and the low voltage level output by the output node A can be fed to a hysteresis circuit to be referenced by the hysteresis circuit. The function and related operation of the hysteresis circuit are well known to a person of average skill in the pertinent art, and additional details are therefore omitted for the sake of brevity.

Please note that the aforementioned resistors R1, R2 are only used as a preferred embodiment of the present invention, but are not meant to be limitations of the present invention. In practical applications, the resistors R1, R2 can be realized by using other impedance devices. In other words, to achieve the same objective of voltage level shifting, the circuit designer only needs to properly choose impedance values of the impedance devices. Furthermore, the present invention does not limit how the resistors R1, R2 are realized in a practical implementation. For example, during the semiconductor process the resistors R1, R2 can be realized by transistors. This alternative design also falls within the scope of the present invention.

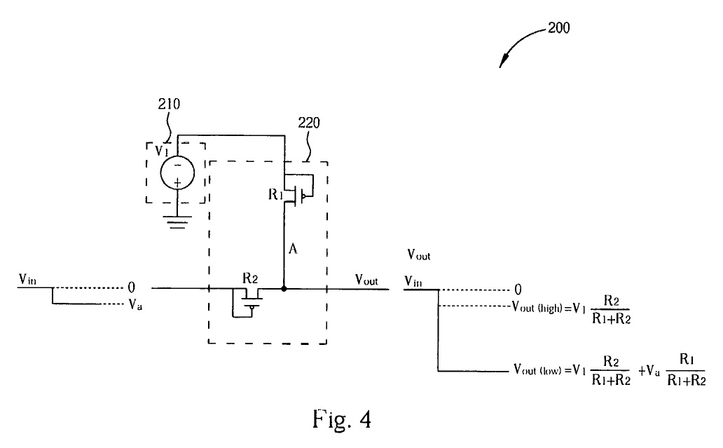

In the aforementioned embodiment, please note that the reference voltage level is a positive voltage level. The present invention can also be implemented by choosing a negative voltage level as the reference voltage level, however. Please refer to FIG. 4. FIG. 4 is a detailed circuit diagram of another embodiment of the level shifter shown in FIG. 2. Comparing the level shifter shown in FIG. 4 with the level shifter shown in FIG. 3, in this embodiment the level shifter 200 uses two transistors as the original resistors R1, R2. As shown in FIG. 4, the gate (control node) and the drain of the transistor R1 are coupled to the reference voltage level 210, and the source of the transistor R1 is coupled to the output node (second voltage level). The gate (control node) and the drain of the transistor R2 are coupled to the first voltage level (input signal Vᵢₙ), and the source of the transistor R2 is coupled to the output node (second voltage level).

In addition, the reference voltage level 210 in this embodiment is a negative voltage level. Therefore, after the voltage dividing operation performed by the voltage dividing circuit 220, a similar level shifting result can be attained via the superposition. Since the related theorem and operation are described in the aforementioned embodiment, additional details are omitted here for the sake of brevity.

Please note that the voltage dividing circuit 220 can use a transistor acting as a resistor, and the other resistor remains the same. This alternative design also falls within the scope of the present invention.

Compared with the prior art, the level shifter of the present invention uses two resistors to form the voltage dividing circuit, achieving the level shifting objective. Therefore, the present invention not only uses fewer circuit components to realize the level shifter function, but also reduces the original high cost caused by implementing too many circuit components in the prior art level shifter.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A level shifter, comprising:
a reference voltage level; and
a voltage dividing circuit, electrically connected to the reference voltage level, a first voltage level, and a second voltage level, wherein the second voltage level is between the reference voltage level and the first voltage level.

2. The level shifter of claim 1, wherein the reference voltage level is a positive voltage level.

3. The level shifter of claim 1, wherein the reference voltage level is a negative voltage level.

4. The level shifter of claim 1, wherein the voltage dividing circuit is implemented utilizing a first impedance unit and a second impedance unit.

5. The level shifter of claim 4, wherein the first impedance unit is a resistor component.

6. The level shifter of claim 4, wherein the first impedance is implemented utilizing a transistor.

7. The level shifter of claim 4, wherein the voltage dividing circuit comprises:
a first resistor, having a node electrically connected to the reference voltage level and another node electrically connected to the second voltage level; and
a second resistor, having a node electrically connected to the first voltage level and another node electrically connected to the second voltage level.

8. The level shifter of claim 1, wherein the voltage dividing circuit comprises:
a first transistor, having a first node and a control node electrically connected to the reference voltage level and a second node electrically connected to the second voltage level; and
a second transistor, having a first node and a control node electrically connected to the first voltage level and a second node electrically connected to the second voltage level.

9. A level shifter, comprising:
a first impedance unit, having a node electrically connected to a reference voltage level and another node electrically connected to a second voltage level; and
a second impedance unit, having a node electrically connected to a first voltage level and another node electrically connected to the second voltage level;
wherein the second voltage level is between the reference voltage level and the first voltage level.

10. The level shifter of claim 9, wherein the reference voltage level is a positive voltage level.

11. The level shifter of claim 9, wherein the reference voltage level is a negative voltage level.

12. The level shifter of claim 9, wherein the first impedance unit is a resistor component.

13. The level shifter of claim 9, wherein the first impedance unit is implemented utilizing a transistor.
